(19) United States
(12) Patent Application Publication
(10) Pub. No.: US 2024/0345490 A1
(43) Pub. Date: Oct. 17, 2024

(54) AN OBJECT GRIPPER, A METHOD OF HOLDING AN OBJECT AND A LITHOGRAPHIC APPARATUS

(71) Applicant: ASML NETHERLANDS B.V., Veldhoven (NL)

(72) Inventor: Paul VAN DONGEN, Wilton, CT (US)

(73) Assignee: ASML NETHERLANDS B.V., Veldhoven (NL)

(21) Appl. No.: 18/294,202

(22) PCT Filed: Jul. 19, 2022
(86) PCT No.: PCT/EP2022/070146

§ 371 Date: Feb. 1, 2024

(30) Foreign Application Priority Data
Aug. 24, 2021 (EP) 21192931.0

(51) Int. Cl. G03F 7/00; B25J 15/06; H01L 21/683

(52) U.S. Cl. CPC G03F 7/707; B25J 15/0658; G03F 7/70341; G03F 7/70875; G03F 7/70925; H01L 21/6838

(57) ABSTRACT

A gripper for an object handler includes an engaging surface for engaging a surface of an object, and a first channel connected to a first outlet, the first outlet being configured to operate, during use, as a vacuum clamp arranged to secure the engaging surface to the surface of the object. The gripper further includes a second channel arranged to be connected to a pressure source, and at least one second outlet arranged adjacent to the engaging surface and connected to the second channel.

### CROSS-REFERENCE TO RELATED APPLICATION

The application claims priority of EP application 211929310 which was filed on 24 Aug. 2021 and which is incorporated herein in its entirety by reference.

### FIELD

The present invention relates to an object gripper for an object handler, a method of holding an object, and a lithographic apparatus.

### BACKGROUND

A lithographic apparatus is a machine constructed to apply a desired pattern onto a substrate. A lithographic apparatus can be used, for example, in the manufacture of integrated circuits (ICs). A lithographic apparatus may, for example, project a pattern (also often referred to as “design layout” or “design”) of a patterning device (e.g., a mask) onto a layer of radiation-sensitive material (resist) provided on a substrate (e.g., a wafer).

As semiconductor manufacturing processes continue to advance, the dimensions of circuit elements have continually been reduced while the amount of functional elements, such as transistors, per device has been steadily increasing over decades, following a trend commonly referred to as ‘Moore's law’. To keep up with Moore's law the semiconductor industry is chasing technologies that enable to create increasingly smaller features. To project a pattern on a substrate a lithographic apparatus may use electromagnetic radiation. The wavelength of this radiation determines the minimum size of features which are patterned on the substrate. Typical wavelengths currently in use are 365 nm (i-line), 248 nm, 193 nm and 13.5 nm. A lithographic apparatus, which uses extreme ultraviolet (EUV) radiation, having a wavelength within a range of 4 nm to 20 nm, for example 6.7 nm or 13.5 nm, may be used to form smaller features on a substrate than a lithographic apparatus which uses, for example, radiation with a wavelength of 193 nm.

Immersion techniques have been introduced into lithographic systems to enable improved resolution of smaller features. In an immersion lithographic apparatus, a liquid layer of immersion liquid having a relatively high refractive index is interposed in a space between a projection system of the apparatus and the substrate. The immersion liquid covers at least the part of the substrate under a final element of the projection system. Thus, at least the portion of the substrate undergoing exposure is immersed in the immersion liquid. The effect of the immersion liquid is to enable imaging of smaller features since the exposure radiation will have a shorter wavelength in the liquid than gas. (The effect of the immersion liquid may also be regarded as increasing the effective numerical aperture (NA) of the system and also increasing the depth of focus.)

In commercial immersion lithography, the immersion liquid is water. Typically the water is distilled water of high purity, such as Ultra-Pure Water (UPW) which is commonly used in semiconductor fabrication plants. In an immersion system, the UPW is often purified and it may undergo additional treatment steps before supply to the immersion space as immersion liquid. Other liquids with a high refractive index can be used besides water can be used as the immersion liquid, for example: a hydrocarbon, such as a fluorohydrocarbon; and/or an aqueous solution. Further, other fluids besides liquid have been envisaged for use in immersion lithography.

Introduction of liquid such as water is not limited to immersion systems. Lithographic systems may also introduce liquids at cleaning stations for substrate processing and distribution locations.

In a lithographic apparatus, one or more object handlers are used to handle objects, where an object is for example a substrate, for example to load and unload a substrate onto and from an object support, e.g. a substrate support, on which the substrate is supported during the lithographic process.

A known object handler comprises a gripper configured to contact and thereby support a substrate from an underside of the substrate. To load the substrate on a substrate support, the substrate support is provided with loading pins that are movable in a vertical direction out of a support surface of the substrate support. The known object handler comprises an actuation system that can arrange the gripper in a position to load the substrate on the extended loading pins. Subsequently, the loading pins can be lowered to place the substrate on the support surface of the substrate support. The support surface of the substrate support may comprise burls on which the substrate is supported. Known substrate supports may use electrostatic clamps to hold the substrate in a fixed position on the substrate support. The electrostatic clamps are activated to clamp the substrate against the burls. Alternatively, known substrate supports may hold the substrate in a fixed position by means of a vacuum.

Water or other fluid on the substrate is known to cause capillary forces between the substrate and the gripper of the substrate. Water can be introduced onto the substrate via e.g. immersion fluid or via cross-contamination from processing and distribution systems. Capillary forces in turn act as controller disturbance forces which can cause errors, system down time and exposure lot abortions. In cases where the controller is able to handle the disturbance forces and proceed with substrate processing, capillary forces can induce undesirable contact between the substrate and machine parts, for example a thermal conditioning unit, resulting in damage to the substrate and/or scanner parts such as the thermal conditioning unit.

Water or other fluid on the substrate may also create a drag force during loading of the substrate onto a substrate support, resulting in improper loading, which in turn may also result in errors and damage. Thermal defects may also be induced by fluid on the substrate, for example due to evaporation of water resulting in a thermal heat load. Local deformation of the substrate may occur as a result.

### SUMMARY

It is an object of the present invention to at least provide an alternative for prior art devices. It is an object of the invention to mitigate one or more disadvantages of the prior art devices. In particular, it is an object of the invention to provide an improved gripper for an object handler to minimise capillary forces between the gripper and an object, to reduce thermal defects of the object, and to reduce damage to the scanner and/or substrate.

According to an aspect of the invention, one or more of the above objects are achieved with a gripper for an object handler. The gripper comprises an engaging surface for engaging a surface of an object. The gripper further comprises a first channel connected to a first outlet, said first outlet being configured to operate, during use, as a vacuum clamp arranged to secure the engaging surface to the surface of the object. The gripper further comprises a second channel arranged to be connected to a pressure source, and at least one second outlet arranged adjacent to the engaging surface and connected to the second channel.

When a pressure is applied through the second channel from a pressure source, and accordingly through the at least one outlet, any liquid in the vicinity of the outlet will be manipulated such that it is no longer in the vicinity of the outlet. The outlet being arranged adjacent to the engaging surface ensures that liquid is removed from the vicinity of the engaging surface. Thus, when the gripper is to be used for handling an object, such as a substrate or a wafer, the likelihood of capillary forces due to residual liquid on either the substrate or the gripper itself is reduced and the vacuum clamp is operable to secure the engaging surface to the surface of the object with reduced risk of sticking. The removal of liquid from a substrate also ensures that thermal loads which can lead to warpage, amongst other defects and damage possibilities, are mitigated.

In an embodiment, the second channel is configured to alternate between operation as a negative pressure line, and operation as a positive pressure line. Advantageously, a single channel may thus be used to provide a suction function to remove liquid in the vicinity of the gripper, and to provide a repulsive function to direct or push liquid away from the vicinity of the gripper. Accordingly, additional channels and outlets are not required.

In an embodiment, the second channel is a negative pressure line configured to apply suction for removal of fluid. Advantageously, the gripper is configured to remove undesirable fluid from the gripper and object.

In an embodiment, the second channel is connected to a wet vacuum supply. Advantageously this ensures a controlled removal and subsequent disposal of any suctioned liquid.

In an embodiment, the pressure in the second channel is in the range of 0 to −55 kPa. Advantageously, such a range ensures a negative pressure application may be achieved without unnecessary expense.

In an embodiment, the second channel is a positive pressure line configured to apply a repulsive force to repel fluid on the surface of the object. Advantageously, liquid is pushed away from the vicinity of the gripper.

In an embodiment, the pressure in the second channel is in the range of 0 to 200 kPa. Advantageously, such a range ensures a positive pressure application without unnecessary expense.

In an embodiment, the at least one outlet of the second channel is located between an outer edge of the gripper and the engaging surface of the gripper. This location of the second outlet has the advantage of removing liquid in the path of the gripper when moving in the direction of the given outer edge of the gripper.

In an embodiment, the at least one second outlet is arranged between the first outlet and the engaging surface of the gripper. This location of the second outlet has the advantage of removing liquid that may be present in the region of the vacuum clamp due to e.g. cross-contamination.

In an embodiment the at least one second outlet is arranged on the leading edge of the gripper. Advantageously, liquid may thus be removed in the path of the gripper when moving in the direction of the leading edge.

In an embodiment, the at least one second outlet is substantially circular. Advantageously, manufacture of the at least one second outlet is kept simple and low cost.

In an embodiment, the at least one second outlet is substantially linear. Advantageously a greater area for pressure application and, accordingly, low pressure resistance, may be provided.

In an embodiment the at least one second outlet is a plurality of second outlets. Advantageously, pressure may be applied to remove liquid at a plurality of locations on the gripper.

In an embodiment the gripper further comprises a groove adjacent to and in communication with the at least one second outlet. Advantageously, directional application of the pressure from the at least one second outlet is enabled to improve the removal of liquid.

In an embodiment, the gripper further comprises a third channel having at least one third outlet connected thereto, said third outlet located adjacent to the at least one second outlet of the second channel. Advantageously, the third channel provides the possibility to apply an additional line of pressure for removal of liquid.

In an embodiment the third channel is configured to alternate between operation as a negative pressure line, and operation as a positive pressure line. Advantageously, flexibility of use for the third channel is provided, as it may be used to provide a suction function to remove liquid in the vicinity of the gripper, or to provide a repulsive function to direct or push liquid away from the vicinity of the gripper.

In an embodiment the third channel is a positive pressure line configured to apply a repulsive force. Advantageously, liquid is pushed away from the vicinity of the gripper.

In an embodiment, the pressure in the third channel is in the range of 0 to 200 kPa. Advantageously, such a range ensures a positive pressure application without unnecessary expense.

In an embodiment the third channel is a negative pressure line configured to apply suction for removal of fluid. Advantageously, the gripper is configured to remove undesirable fluid from the gripper and object.

In an embodiment the pressure in the third channel is in the range of 0 to −55 kPa. Advantageously, such a range ensures a negative pressure application may be achieved without unnecessary expense.

In an embodiment the at least one third outlet is substantially circular. Advantageously, manufacture of the at least one second outlet is kept simple and low cost.

In an embodiment the at least one third outlet is substantially linear. Advantageously a greater area for pressure application and, accordingly, low pressure resistance, may be provided.

In an embodiment the at least one third outlet is a plurality of third outlets. Advantageously, pressure may be applied to remove liquid at a plurality of locations on the gripper.

In an embodiment the gripper further comprises a groove adjacent to and in communication with the at least one third outlet. Advantageously, directional application of the pressure from the at least one second outlet is enabled to improve the removal of liquid.

In an embodiment the at least one third outlet of the third channel is arranged to cooperate with the at least one second outlet of the second channel. Advantageously, removal of liquid from the object and/or the gripper becomes more efficient.

In an embodiment, the application of pressure to the second and/or third channels is configured to control a temperature of the object. Advantageously, thermal defects are reduced.

In an embodiment, the engaging surface further comprises a porous material. Advantageously, the porous material absorbs fluid in the vicinity of the gripper.

In an embodiment the engaging surface further comprises a hydrophilic or hydrophobic coating. Advantageously the gripper is configured to attract or repel fluid, respectively.

In an embodiment the engaging surface of the gripper is shaped by one or more lines. Advantageously, the engaging surface may be selected to follow at least partially the contours of the gripper, or vacuum clamp.

In an embodiment the one or more lines are straight.

In an embodiment the one or more lines are curved.

In an embodiment the one or more lines form a continuous surface.

The invention further relates to a lithographic apparatus for receiving an object such as a substrate, comprising a projection system for protecting a pattern onto said substrate and the gripper of the invention. Advantageously, the pattern can be projected more accurately, because the object has been positioned more accurately.

The invention further relates to a method of holding an object comprising: locating a gripper according to the invention underneath an object, applying a first pressure through the second channel, removing the first pressure through the second channel, and applying a vacuum to operate a vacuum clamp to secure the substrate to the gripper. Advantageously, a method of holding an object wherein defects due to e.g. capillary forces are reduced is provided.

In an embodiment, the method comprises locating a gripper comprising a third channel according to the invention, and further comprising applying a second pressure through the third channel. Advantageously, a method of holding an object wherein defects due to e.g. capillary forces are reduced is provided.

In an embodiment the first pressure and the second pressure are configured to cooperatively remove liquid. Advantageously, liquid on the object and/or gripper is removed and an efficient method of holding an object wherein defects due to e.g. capillary forces are reduced is provided.

In an embodiment the first pressure is a negative pressure to remove fluid from the vicinity of the at least one outlet. Advantageously, the first pressure is configured to remove undesirable fluid from the gripper and object.

In an embodiment the first pressure is a positive pressure to repel fluid from the vicinity of the at least one outlet. Advantageously, the first pressure is configured to repel undesirable fluid away from the gripper and object.

In an embodiment the second pressure is a negative pressure to remove fluid from the vicinity of the at least one outlet of the third channel. Advantageously, the second pressure is configured to remove undesirable fluid from the gripper and object.

In an embodiment the second pressure is a positive pressure to repel fluid from the vicinity of the at least one outlet of the third channel. Advantageously, the second pressure is configured to repel undesirable fluid away from the gripper and object.

In an embodiment the pressure is configured to control a temperature of the object. Advantageously, thermal defects are reduced.

The invention further relates to a computer program comprising computer readable instructions configured to cause a computer to carry out the method according to the invention.

The invention further relates to a computer readable medium carrying a computer program according to the invention.

The invention further relates to a computer apparatus comprising: a memory storing processor readable instructions; and a processor arranged to read and execute instructions stored in said memory; wherein said processor readable instructions comprise instructions arranged to control the computer to carry out a method according to the invention.

### BRIEF DESCRIPTION OF THE DRAWINGS

Embodiments of the invention will now be described, by way of example only, with reference to the accompanying schematic drawings, in which:

FIG. 1 depicts a schematic overview of a lithographic apparatus;

FIG. 2 depicts a detailed view of a part of the lithographic apparatus of FIG. 1;

FIG. 3 schematically depicts a position control system;

FIG. 4A shows a side view of a stage apparatus which comprises an object support;

FIG. 4B schematically shows an object handler in a top view;

FIG. 5A schematically shows a top view of part of a gripper;

FIG. 5B schematically shows a side-view cross-section of part of a gripper;

FIG. 6A shows a top view of an embodiment of part of a gripper according to the invention;

FIG. 6B shows a top view of an embodiment of part of a gripper according to the invention;

FIG. 7 shows a top view of an embodiment of part of a gripper according to the invention;

FIG. 8 shows a side view cross-section of part of a gripper according to an embodiment of the invention;

FIG. 9A shows a top view of an embodiment of part of a gripper according to the invention;

FIG. 9B shows a top view of an embodiment of part of a gripper according to the invention;

FIG. 9C shows a top view of an embodiment of part of a gripper according to the invention.

### DETAILED DESCRIPTION

In the present document, the terms “radiation” and “beam” are used to encompass all types of electromagnetic radiation, including ultraviolet radiation (e.g. with a wavelength of 365, 248, 193, 157 or 126 nm) and EUV (extreme ultra-violet radiation, e.g. having a wavelength in the range of about 5-100 nm).

The term “reticle”, “mask” or “patterning device” as employed in this text may be broadly interpreted as referring to a generic patterning device that can be used to endow an incoming radiation beam with a patterned cross-section, corresponding to a pattern that is to be created in a target portion of the substrate. The term “light valve” can also be used in this context. Besides the classic mask (transmissive or reflective, binary, phase-shifting, hybrid, etc.), examples of other such patterning devices include a programmable mirror array and a programmable LCD array.

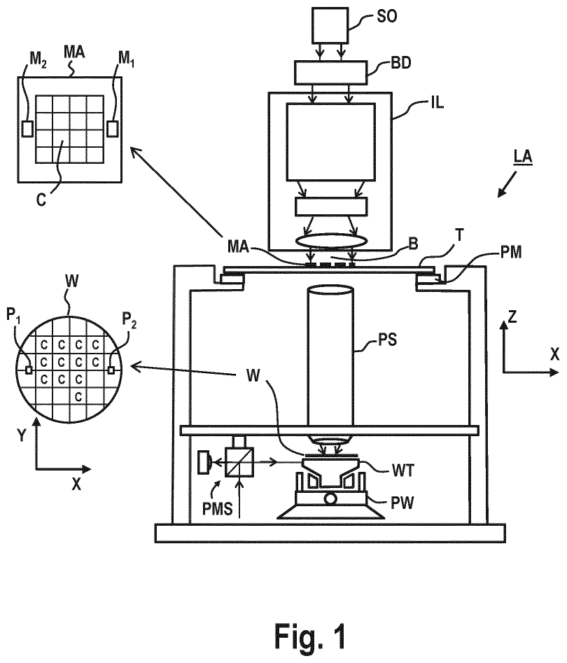

FIG. 1 schematically depicts a lithographic apparatus LA. The lithographic apparatus LA includes an illumination system (also referred to as illuminator) IL configured to condition a radiation beam B (e.g., UV radiation, DUV radiation or EUV radiation), a mask support (e.g., a mask table) MT constructed to support a patterning device (e.g., a mask) MA and connected to a first positioner PM configured to accurately position the patterning device MA in accordance with certain parameters, a substrate support (e.g., a wafer table) WT constructed to hold a substrate (e.g., a resist coated wafer) W and connected to a second positioner PW configured to accurately position the substrate support in accordance with certain parameters, and a projection system (e.g., a refractive projection lens system) PS configured to project a pattern imparted to the radiation beam B by patterning device MA onto a target portion C (e.g., comprising one or more dies) of the substrate W.

In operation, the illumination system IL receives a radiation beam from a radiation source SO, e.g. via a beam delivery system BD. The illumination system IL may include various types of optical components, such as refractive, reflective, magnetic, electromagnetic, electrostatic, and/or other types of optical components, or any combination thereof, for directing, shaping, and/or controlling radiation. The illuminator IL may be used to condition the radiation beam B to have a desired spatial and angular intensity distribution in its cross section at a plane of the patterning device MA.

The term “projection system” PS used herein should be broadly interpreted as encompassing various types of projection system, including refractive, reflective, catadioptric, anamorphic, magnetic, electromagnetic and/or electrostatic optical systems, or any combination thereof, as appropriate for the exposure radiation being used, and/or for other factors such as the use of an immersion liquid or the use of a vacuum. Any use of the term “projection lens” herein may be considered as synonymous with the more general term “projection system” PS.

The lithographic apparatus LA may be of a type wherein at least a portion of the substrate may be covered by a liquid having a relatively high refractive index, e.g., water, so as to fill a space between the projection system PS and the substrate W—which is also referred to as immersion lithography. More information on immersion techniques is given in U.S. Pat. No. 6,952,253, which is incorporated herein by reference.

The lithographic apparatus LA may also be of a type having two or more substrate supports WT (also named “dual stage”). In such “multiple stage” machine, the substrate supports WT may be used in parallel, and/or steps in preparation of a subsequent exposure of the substrate W may be carried out on the substrate W located on one of the substrate support WT while another substrate W on the other substrate support WT is being used for exposing a pattern on the other substrate W.

In addition to the substrate support WT, the lithographic apparatus LA may comprise a measurement stage. The measurement stage is arranged to hold a sensor and/or a cleaning device. The sensor may be arranged to measure a property of the projection system PS or a property of the radiation beam B. The measurement stage may hold multiple sensors. The cleaning device may be arranged to clean part of the lithographic apparatus, for example a part of the projection system PS or a part of a system that provides the immersion liquid. The measurement stage may move beneath the projection system PS when the substrate support WT is away from the projection system PS.

In operation, the radiation beam B is incident on the patterning device, e.g. mask, MA which is held on the mask support MT, and is patterned by the pattern (design layout) present on patterning device MA. Having traversed the mask MA, the radiation beam B passes through the projection system PS, which focuses the beam onto a target portion C of the substrate W. With the aid of the second positioner PW and a position measurement system IF, the substrate support WT can be moved accurately, e.g., so as to position different target portions C in the path of the radiation beam B at a focused and aligned position. Similarly, the first positioner PM and possibly another position sensor (which is not explicitly depicted in FIG. 1) may be used to accurately position the patterning device MA with respect to the path of the radiation beam B. Patterning device MA and substrate W may be aligned using mask alignment marks M1, M2 and substrate alignment marks P1, P2. Although the substrate alignment marks P1, P2 as illustrated occupy dedicated target portions, they may be located in spaces between target portions. Substrate alignment marks P1, P2 are known as scribe-lane alignment marks when these are located between the target portions C.

To clarify the invention, a Cartesian coordinate system is used. The Cartesian coordinate system has three axes, i.e., an x-axis, a y-axis and a z-axis. Each of the three axes is orthogonal to the other two axes. A rotation around the x-axis is referred to as an Rx-rotation. A rotation around the y-axis is referred to as an Ry-rotation. A rotation around about the z-axis is referred to as an Rz-rotation. The x-axis and the y-axis define a horizontal plane, whereas the z-axis is in a vertical direction. The Cartesian coordinate system is not limiting the invention and is used for clarification only. Instead, another coordinate system, such as a cylindrical coordinate system, may be used to clarify the invention. The orientation of the Cartesian coordinate system may be different, for example, such that the z-axis has a component along the horizontal plane.

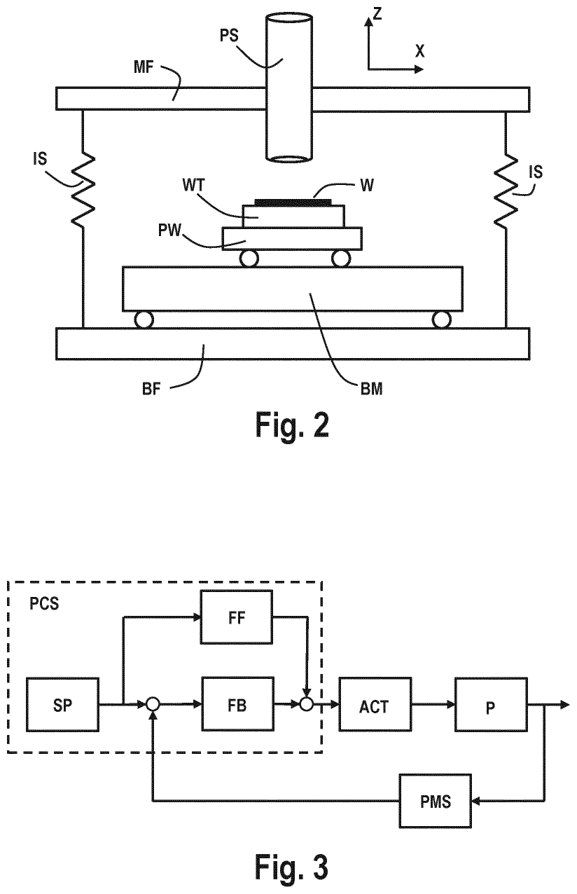

FIG. 2 shows a more detailed view of a part of the lithographic apparatus LA of FIG. 1. The lithographic apparatus LA may be provided with a base frame BF, a balance mass BM, a metrology frame MF and a vibration isolation system IS. The metrology frame MF supports the projection system PS. Additionally, the metrology frame MF may support a part of the position measurement system PMS. The metrology frame MF is supported by the base frame BF via the vibration isolation system IS. The vibration isolation system IS is arranged to prevent or reduce vibrations from propagating from the base frame BF to the metrology frame MF.

The second positioner PW is arranged to accelerate the substrate support WT by providing a driving force between the substrate support WT and the balance mass BM. The driving force accelerates the substrate support WT in a desired direction. Due to the conservation of momentum, the driving force is also applied to the balance mass BM with equal magnitude, but at a direction opposite to the desired direction. Typically, the mass of the balance mass BM is significantly larger than the masses of the moving part of the second positioner PW and the substrate support WT.

In an embodiment, the second positioner PW is supported by the balance mass BM. For example, wherein the second positioner PW comprises a planar motor to levitate the substrate support WT above the balance mass BM. In another embodiment, the second positioner PW is supported by the base frame BF. For example, wherein the second positioner PW comprises a linear motor and wherein the second positioner PW comprises a bearing, like a gas bearing, to levitate the substrate support WT above the base frame BF.

The position measurement system PMS may comprise any type of sensor that is suitable to determine a position of the substrate support WT. The position measurement system PMS may comprise any type of sensor that is suitable to determine a position of the mask support MT. The sensor may be an optical sensor such as an interferometer or an encoder. The position measurement system PMS may comprise a combined system of an interferometer and an encoder. The sensor may be another type of sensor, such as a magnetic sensor. a capacitive sensor or an inductive sensor. The position measurement system PMS may determine the position relative to a reference, for example the metrology frame MF or the projection system PS. The position measurement system PMS may determine the position of the substrate table WT and/or the mask support MT by measuring the position or by measuring a time derivative of the position, such as velocity or acceleration.

The position measurement system PMS may comprise an encoder system. An encoder system is known from for example, United States patent application US2007/0058173A1, filed on Sep. 7, 2006, hereby incorporated by reference. The encoder system comprises an encoder head, a grating and a sensor. The encoder system may receive a primary radiation beam and a secondary radiation beam. Both the primary radiation beam as well as the secondary radiation beam originate from the same radiation beam, i.e., the original radiation beam. At least one of the primary radiation beam and the secondary radiation beam is created by diffracting the original radiation beam with the grating. If both the primary radiation beam and the secondary radiation beam are created by diffracting the original radiation beam with the grating, the primary radiation beam needs to have a different diffraction order than the secondary radiation beam. Different diffraction orders are, for example, +1^{st} order, −1^{st} order, +2^{nd} order and −2^{nd} order. The encoder system optically combines the primary radiation beam and the secondary radiation beam into a combined radiation beam. A sensor in the encoder head determines a phase or phase difference of the combined radiation beam. The sensor generates a signal based on the phase or phase difference. The signal is representative of a position of the encoder head relative to the grating. One of the encoder head and the grating may be arranged on the substrate structure WT. The other of the encoder head and the grating may be arranged on the metrology frame MF or the base frame BF. For example, a plurality of encoder heads is arranged on the metrology frame MF, whereas a grating is arranged on a top surface of the substrate support WT. In another example, a grating is arranged on a bottom surface of the substrate support WT, and an encoder head is arranged below the substrate support WT.

The position measurement system PMS may comprise an interferometer system. An interferometer system is known from, for example, U.S. Pat. No. 6,020,964, filed on Jul. 13, 1998, hereby incorporated by reference. The interferometer system may comprise a beam splitter, a mirror, a reference mirror and a sensor. A beam of radiation is split by the beam splitter into a reference beam and a measurement beam. The measurement beam propagates to the mirror and is reflected by the mirror back to the beam splitter. The reference beam propagates to the reference mirror and is reflected by the reference mirror back to the beam splitter. At the beam splitter, the measurement beam and the reference beam are combined into a combined radiation beam. The combined radiation beam is incident on the sensor. The sensor determines a phase or a frequency of the combined radiation beam. The sensor generates a signal based on the phase or the frequency. The signal is representative of a displacement of the mirror. In an embodiment, the mirror is connected to the substrate support WT. The reference mirror may be connected to the metrology frame MF. In an embodiment, the measurement beam and the reference beam are combined into a combined radiation beam by an additional optical component instead of the beam splitter.

The first positioner PM may comprise a long-stroke module and a short-stroke module. The short-stroke module is arranged to move the mask support MT relative to the long-stroke module with a high accuracy over a small range of movement. The long-stroke module is arranged to move the short-stroke module relative to the projection system PS with a relatively low accuracy over a large range of movement. With the combination of the long-stroke module and the short-stroke module, the first positioner PM is able to move the mask support MT relative to the projection system PS with a high accuracy over a large range of movement. Similarly, the second positioner PW may comprise a long-stroke module and a short-stroke module. The short-stroke module is arranged to move the substrate support WT relative to the long-stroke module with a high accuracy over a small range of movement. The long-stroke module is arranged to move the short-stroke module relative to the projection system PS with a relatively low accuracy over a large range of movement. With the combination of the long-stroke module and the short-stroke module, the second positioner PW is able to move the substrate support WT relative to the projection system PS with a high accuracy over a large range of movement.

The first positioner PM and the second positioner PW each are provided with an actuator to move respectively the mask support MT and the substrate support WT. The actuator may be a linear actuator to provide a driving force along a single axis, for example the y-axis. Multiple linear actuators may be applied to provide driving forces along multiple axis. The actuator may be a planar actuator to provide a driving force along multiple axis. For example, the planar actuator may be arranged to move the substrate support WT in 6 degrees of freedom. The actuator may be an electro-magnetic actuator comprising at least one coil and at least one magnet. The actuator is arranged to move the at least one coil relative to the at least one magnet by applying an electrical current to the at least one coil. The actuator may be a moving-magnet type actuator, which has the at least one magnet coupled to the substrate support WT respectively to the mask support MT. The actuator may be a moving-coil type actuator which has the at least one coil coupled to the substrate support WT respectively to the mask support MT. The actuator may be a voice-coil actuator, a reluctance actuator, a Lorentz-actuator or a piezo-actuator, or any other suitable actuator.

The lithographic apparatus LA comprises a position control system PCS as schematically depicted in FIG. 3. The position control system PCS comprises a setpoint generator SP, a feedforward controller FF and a feedback controller FB. The position control system PCS provides a drive signal to the actuator ACT. The actuator ACT may be the actuator of the first positioner PM or the second positioner PW. The actuator ACT drives the plant P, which may comprise the substrate support WT or the mask support MT. An output of the plant P is a position quantity such as position or velocity or acceleration. The position quantity is measured with the position measurement system PMS. The position measurement system PMS generates a signal, which is a position signal representative of the position quantity of the plant P. The setpoint generator SP generates a signal, which is a reference signal representative of a desired position quantity of the plant P. For example, the reference signal represents a desired trajectory of the substrate support WT. A difference between the reference signal and the position signal forms an input for the feedback controller FB. Based on the input, the feedback controller FB provides at least part of the drive signal for the actuator ACT. The reference signal may form an input for the feedforward controller FF. Based on the input, the feedforward controller FF provides at least part of the drive signal for the actuator ACT. The feedforward FF may make use of information about dynamical characteristics of the plant P, such as mass, stiffness, resonance modes and eigenfrequencies.

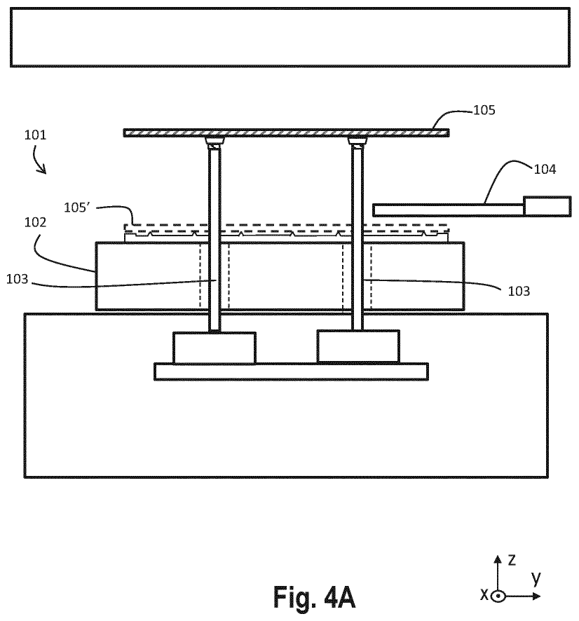

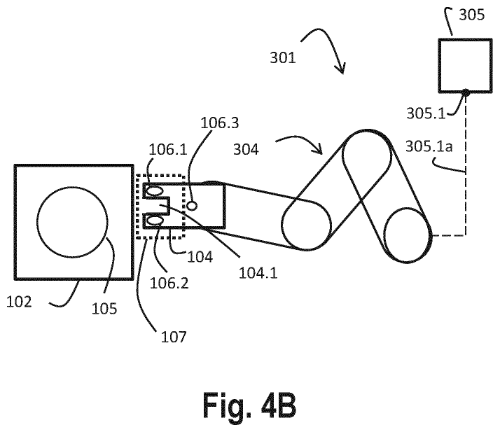

FIG. 4A shows a side view of a stage apparatus 101 which comprises an object support 102 configured to support an object 105, which e.g. is a substrate W or a wafer. The object support 102 may e.g. be supported by another support as shown in FIG. 4A. The stage apparatus 101 is arranged to receive the object 105 from an object gripper 104. In the example shown in FIG. 4A, the stage apparatus 101 comprises a plurality of support members 103, for example loading pins, to support the object 105 and lower said object onto the object support 102. Reference 105′ illustrates the lowered position of the object on the object support 102. The skilled person will be aware that the stage apparatus is not limited to one having the components as illustrated in the example in FIG. 4A and may, for example, not comprise loading pins.

FIG. 4B schematically shows an object handler 301 in a top view. It is noted that for the sake of clarity FIG. 4B does not depict all components, but focuses on those relevant for the explanation that follows. The object handler 301 comprises a robot arm 304, configured to provide the object 105 to the object support 102, and a control unit 305. Robot arm 304 may also be a linear movement system. FIG. 4B further shows that the control unit 305 has a first output terminal 305.1 for controlling the robot arm 304 with a first control signal 305.1a. The robot arm 304 comprises the object gripper 104, and the position of the object gripper 104 can thus be controlled as such. Since the gripper 104 arranges the object 105 above the object support 102, the position of the object 105 relative to the object support 102 can be controlled as such. The robot arm 304 may further be able to repeat its movement repetitively with high precision, such that each object 105 can be arranged on substantially the same position relative to the object support 102.

FIG. 4B shows that the gripper 104 in the shown embodiment comprises a first vacuum clamp 106.1, a second vacuum clamp 106.2, and a third vacuum clamp 106.3. Vacuum clamps 106.1, 106.2, 106.3 are located on the gripper body. A recess 104.1 may further be provided in the object gripper 104, e.g. to allow support members of the stage apparatus if present to engage the object 105. In the embodiment shown in FIG. 4B therefore, the gripper 104 has two fingers, projecting either side of recess 104.1. It is noted that gripper 104 may have fingers that are narrower or wider relative to the width of the gripper body as shown in the example of FIG. 4B, or there may be no recess 104.1 present at all. The vacuum clamps 106.1, 106.2, 106.3 are fluidly connected to one or more non-shown vacuum sources, which provide a low or negative pressure on the object 105 to enable suction and vacuum clamping in use. A negative pressure in the context of the present disclosure means a pressure lower than ambient pressure. Removal of the vacuum source results in release of the vacuum clamps. To load an object 105 onto e.g. an object holder 102, the gripper 104 is actuated by robot arm 304 to position vacuum clamps 106.1, 106.2, 106.3 beneath the underside (i.e. adjacent the bottom surface) of the object 105, whereupon a negative pressure is applied to vacuum clamps 106.1, 106.2, 106.3, thereby securing the bottom surface of the object 105 to the gripper 104 by means of a vacuum. Robot arm 304 is then actuated further to move the gripper which thus carries object 105 to the desired location, e.g. to object holder 102. When the object 105 is in the desired position, the negative pressure applied through vacuum clamps 106.1, 106.2, 106.3 is released, and the object 105 is released from the object gripper 104. Unloading of the object 105 follows the same sequence: gripper 104 is actuated by robot arm 304 to position vacuum clamps 106.1, 106.2, 106.3 beneath the underside (i.e. adjacent the bottom surface) of the object 105, negative pressure is applied to said vacuum clamps 106.1, 106.2, 106.3 to secure the bottom surface of the object 105 to the gripper by means of a vacuum, then the robot arm 304 is actuated further to move the gripper 104 and object 105 to a desired location, e.g. an unloading stage, whereupon the negative pressure is removed to release the vacuum clamps 106.1, 106.2, 106.3, and release the object 105. The object gripper used for unloading of the object 105 may be an object gripper which is different from the object gripper 104 used for providing the object 105, e.g. both grippers may be arranged on opposite sides of the object 105, e.g. on the left and right side in FIG. 4B. It is noted that the object gripper may not be limited to securing an object at its bottom surface, as disclosed in the embodiment above: the arrangement of the stage apparatus and object handler may enable an object to be secured at its top surface. In such instance, the gripper will be configured to move above the object, and vacuum clamps 106.1, 106.2, 106.3 will be arranged on the lower surface of the gripper, so as to be positioned adjacent to the top surface of the object.

When liquid such as water is present on the surface of the object to be clamped or on the gripper itself due to e.g. immersion liquid or cross-contamination, capillary forces between the gripper 104 and the object 105 can be induced when securing the object to the gripper. Capillary forces can lead to sticking of the object 105 on the gripper even after release of the vacuum clamps 106.1, 106.2, 106.3. Sticking in turn can lead to warpage and/or vibration of the object, and other defects. Alternatively, or in addition to the effects of capillary forces, liquid on the object can induce thermal defects, and to reduce damage to the scanner and/or object.

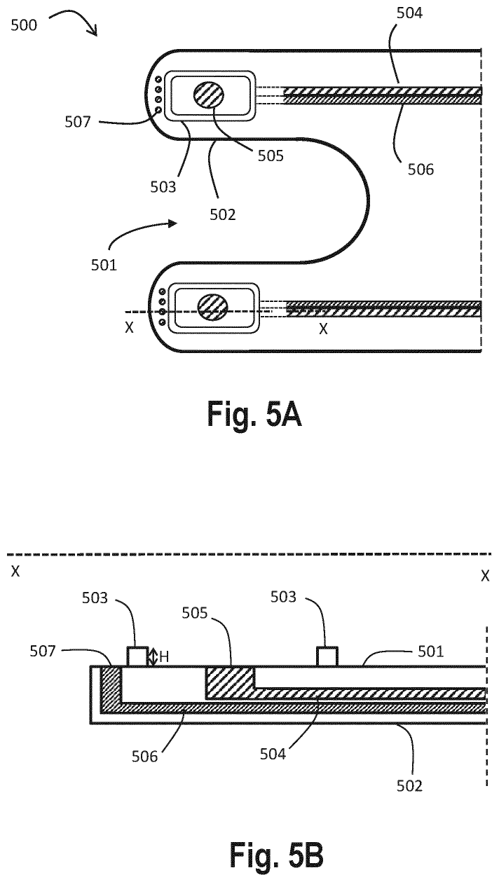

It is therefore desirable to provide means to remove liquid from a gripper and/or avoiding liquid from reaching a gripper before securing an object. A gripper that is configured to provide pneumatic control of liquid in its vicinity is therefore proposed. FIG. 5A depicts a schematic top view of a front part of a gripper 500 according to an embodiment of the invention. For context, the partial area of the gripper body shown in FIG. 5 corresponds to that in demarcated area 107 in FIG. 4B. A gripper 500 may comprise a recess 501, such that two fingers of the gripper body 502 are defined. The gripper comprises a bumper-like engaging surface 503 for engaging the surface of an object, which may be a substrate. The engaging surface 503 has a height H typically no more than a fraction of a millimetre, thus on the order of a few hundred microns. It is the intention of the embodiments in this disclosure that liquid is substantially reduced or removed from the gripper at least on and in the vicinity of the engaging surface. A first channel 504 is provided, connected to a first outlet 505 and configured to operate during use as a vacuum clamp for securing the engaging surface 503 of the gripper 500 to the substrate. Such vacuum clamps are known in the art and may for example be connected to a negative pressure source (not shown), of between 0 to −55 kPa. The person skilled in the art will recognise that the pressure source for the vacuum clamps need not limited to the aforementioned pressure range and may be optimised to a value outside of the stated range. The engaging surface 503 surrounds the first outlet 505 such that when the first outlet 505 is operated as a vacuum clamp and the engaging surfaces engages an object to be clamped, the engaging surface 503 defines a volume to be evacuated. Accordingly, the engaging surface 503 comprises any appropriate material for material handling applications that may be used to define an evacuation volume, for example an anti-static plastic material. The first channel 504 may be at least partially integrally formed within gripper 500, for example within a finger 502, and may not be visible on the gripper surface. The gripper 500 further comprises a second channel 506, said second channel 506 having at least one outlet 507 arranged adjacent to the engaging surface 503. The second channel 506 is connected to a pressure source (not shown). The outlets of the second channel are accordingly pneumatic control outlets. The first and second channels 504, 506 may be located adjacent to each other, and may be at least partially integrated into the gripper 500, for example within a finger 502. The first and second channels 504, 506 may at least partially overlap, or may be spatially separated. For the purposes of illustration throughout this disclosure, the first and second channels 504, 506 are not drawn in full and their connections to the first and second outlets 505, 507 are not shown.

In FIG. 5A, the gripper body 502 comprises two engaging surfaces 503 and two sets of second outlets 507. It is noted that for all embodiments of this disclosure, the number and shape of the engaging surfaces and pneumatic control outlets on a gripper may be any appropriate number and arrangement, for example to scale with the size of the object handler, gripper and/or object to be handled. The arrangement of the engaging surface and outlets may be sized so as the area covers, in part or in whole, the surface area of the operable gripper body 502, which may for example be the surface area determined by the boundary of a gripper finger.

In an embodiment, the pressure source serving the second channel 506 is a negative or low pressure source, wherein the low or negative pressure applied through the second channel 506 may be between 0 to −55 kPa. The pressure source may be a dedicated wet vacuum source, wherein a wet vacuum is a vacuum that is capable of removing a given quantity of fluid via suction and may be provided by, e.g., a hydraulic pump. The pressure source may be different to the source connected to the first channel 504 for operating the vacuum clamps, or may alternatively be the same source. The person skilled in the art will recognise that the pressure source for the second channel 506 need not be limited to the aforementioned pressure range and may be optimised to a value outside of the stated range. For example, the pressure applied through the second channel 506 may reach values lower than −55 kPa. The second channel 506 and its corresponding at least one outlet 507 in this embodiment serves as an extraction line to remove liquid in the vicinity of the at least one outlet 507. Accordingly, liquid is prevented from reaching and/or is removed from the vicinity of the engaging surface 503. The at least one outlet 507 is of an appropriate size to achieve a low pressure resistance to enable suction and removal of fluid. The dimensions of the at least one outlet are thus preferably on the order of several millimetres, however dimensions on the order of 100-200 μm may also be used. The shape of the at least one outlet 507 is limited only by function and may therefore take any appropriate form. Optionally, the shape of the at least one outlet 507 may be substantially circular. Alternatively, the shape of the at least one outlet 507 may be substantially linear, for example rectangular. Alternatively, the at least one outlet 507 may be oval-shaped. The at least one outlet 507 may comprise a plurality of outlets. Where the at least one outlet 507 comprises a plurality of outlets, the outlets may be of different shapes and/or sizes. Furthermore, the plurality of outlets may have regular or irregular spacing across part or all of the gripper 500.

FIG. 5B illustrates a cross-section through the line X-X marked on FIG. 5A. The first channel 504 and second channel 506 are for the purposes of illustration shown in FIG. 5B as being integrated in the gripper body 502 and positioned adjacent to each other in a vertical direction. However, it is noted that channels 504 and 506 may alternatively be positioned adjacent to each other, and/or on a surface of the gripper body 502. Furthermore, channels 504 and 506 may be only partially integrated into the gripper body 502.

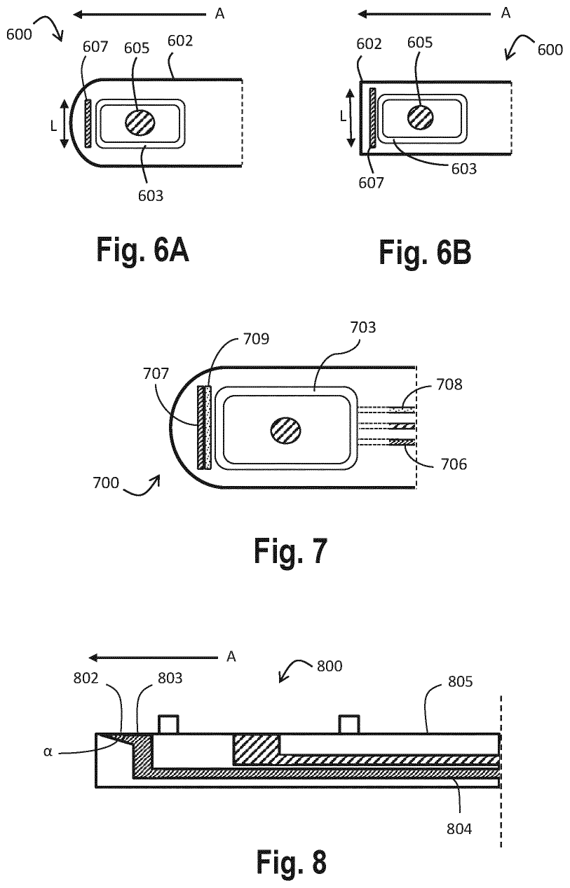

An exemplary embodiment of part of a gripper 600 is illustrated in FIG. 6A. A continuous ring-shaped bumper-like engaging surface 603 is provided, surrounding the first outlet 605. The second channel (not shown) is connected to a single outlet 607, the outlet being provided adjacent to engaging surface 603. The single outlet 607 has a length L that substantially corresponds to the length of the engaging surface 603 on a leading edge of the gripper 600. The outlet in this embodiment therefore comprises a trench with dimensions on the order of several millimetres and is thus readily visible with the naked eye. Liquid is typically encountered by a gripper when approaching an object to be handled, therefore it is preferable that the at least one outlet 607 is located on the leading edge of the gripper body 602. The at least one outlet 607 on the leading edge of the gripper 600 has the advantage of removing liquid in the path of the gripper 600 when moving in the direction of the leading edge, as indicated by the arrow A in FIG. 6A. Accordingly, liquid is removed from the path of the engaging surface 603.

FIG. 6B illustrates a further exemplary embodiment of a part of a gripper 600. In the example of FIG. 6B, the part of the gripper 600 is a finger having a rectangular shape. Similar to the embodiment of FIG. 6A, a continuous ring-shaped bumper-like engaging surface 603 surrounds the first outlet 605. The second channel (not shown) is connected to a single outlet 607 located forward of the leading edge of the engaging surface 603. The outlet 607 has a length L that substantially corresponds to the width of the finger of the gripper body 602. The shape of the finger in FIG. 6B advantageously enables an outlet 607 of greater length and closer to the leading edge than the embodiment of FIG. 6A, thereby providing the capability to remove liquid from a larger area. A single outlet 607 as shown in the example embodiments of FIGS. 6A and 6B is advantageously straightforward and inexpensive to manufacture as well as providing an operative region to direct an applied pressure across a substantial portion if not the whole length of the leading edge of the gripper body 602.

The engaging surface 603 may be shaped independently of the gripper body or may alternatively at least partly follow the contour of the gripper body.

Optionally, the bumper-like engaging surface 603 may take the form of a curved continuous line, for example in the shape of a closed horseshoe, ring (as illustrated in FIG. 6A), or spiral.

Optionally, the bumper-like engaging surface 603 is formed by a plurality of connected straight lines, for example forming the perimeter of a square, rectangle, or any other appropriate form.

Optionally, the engaging surface 603 may comprise a combination of curved and straight continuous lines.

Optionally, there may be more than one engaging surface 603 on a gripper 600.

In an embodiment, the pressure source serving the second channel 506, 606 is a positive or high pressure line wherein the positive or high pressure source applied through the second channel 506, 606 may be a compressed dry air source with a pressure on the order of 0-200 kPa. The person skilled in the art will recognise that the pressure source for the second channel 506, 606 need not be limited to the aforementioned pressure range and may be optimised to a value outside of the stated range. The second channel 506, 606 and its corresponding at least one outlet in this embodiment 507, 607 serves as a repulsive force applicator to direct fluid droplets in an opposing direction to the applied positive pressure. In this way, liquid is directed away from the engaging surface 503, 603. The at least one outlet 507, 607 is of an appropriate size so as when combined with the selected positive pressure a repulsive force to repel fluid away from the gripper 500, 600 is provided. For example, the at least one outlet 507, 607 may have dimensions on the order of 100-200 μm. An outlet with a length on the order of 100-200 μm is typically manufactured more easily and cheaply than an outlet with smaller dimensions, however the dimensions are not limited to this range. The shape and size of the at least one outlet 507, 607 is limited only by function and may therefore take any appropriate form. The engaging surface 503, 603, at least one outlet 507, 607 or plurality of outlets may take any form and size as described in the embodiments above wherein the pressure source to the second channel is a low or negative pressure source, and the at least one outlet 507, 607 may also be a plurality of outlets as described above.

In an embodiment, the second channel 506, 606 is connected to a pressure source or system which may alternatively apply a positive pressure or a negative pressure in accordance with the description above.

In an embodiment the pressure source can alternate between application of a negative pressure or a positive pressure to the second channel. For example, the pressure source may comprise a system capable of switching between provision of a negative or low pressure and a positive or high pressure. A switchable pressure source has the advantage of alternately providing a suction function to remove liquid in the vicinity of the gripper, and to provide a repulsive function to direct or push liquid away from the vicinity of the gripper, without requiring further modifications on the gripper, such as additional channels and outlets. Thus, a simple fluid/pneumatic control gripper is provided.

In a further embodiment, shown in an exemplary embodiment in FIG. 7, the gripper 700 further comprises a third channel 708 having at least one outlet 709 located adjacent to the engaging surface 703. For the purposes of illustration throughout this disclosure, the third channel 708, similar to the first and second channels, is not drawn in full and its connection to its at least one outlet 709 is not shown. Said third channel 708 is connected to a pressure source (not shown), which may be an alternating pressure source as disclosed in the previous embodiment. Alternatively, the pressure source may be a high or positive pressure source, such that the third channel 708 is a dedicated high pressure line. Alternatively, the pressure source may be a low or negative pressure source, such that the third channel 708 is a dedicated low pressure line. It is intended that when the third channel 708 is connected to a high pressure source so as to be operable as a high pressure line, the second channel 706 is operable as a low or negative pressure line. Similarly, it is intended that when the third channel 708 is connected to a low pressure source so as to be operable as a low pressure line, the second channel 706 is operable as a high or positive pressure line. In this way, the second and third channels 706, 708 may function cooperatively: the one or more outlets of the positive pressure line will repel liquid from the gripper 700, while the one or more outlets of the negative pressure line will provide suction to remove liquid from the gripper.

In a preferred embodiment, the at least one outlet 709 of the positive pressure line 708 is arranged to provide a repulsive force in the direction of the at least one outlet 707 of the negative pressure line 706, such that in use water may be repelled from the at least one outlet 709 of the positive pressure line towards the at least one outlet 707 of the negative pressure line, thereby increasing the efficiency of liquid removal from the gripper 700. In the embodiment of this preferred functionality shown in FIG. 7, a single positive pressure outlet 709 is provided immediately adjacent to a single negative pressure outlet 707 of equal length. The preferred functionality is not limited to this particular layout: pneumatic control of fluid removal from one or more regions on the object to be handled and the gripper may be optimised via selection of one or more positive pressure outlets configured to cooperatively operate in tandem with one or more negative pressure outlets.

Optionally, as illustrated in FIG. 8 in a side-view cross-section, the gripper 800 may further comprise a groove or angled indent 802 adjacent to and in communication with the at least one outlet 803 of either or both of the second and/or third channels 804, or at least one of a plurality of outlets. The groove or indent 802 enables directional application of the pressure from the at least one outlet 803. In the exemplary embodiment of FIG. 8, the groove 802 forms an angle α relative to the top surface plane of the gripper body 805, thus the groove induces a tilt of the outlet 802, which in this embodiment is in the direction of movement of the gripper, indicated by the arrow A. Such an angle α may for example be a 45° angle, however it is noted that the shape of the groove 802 may be one of a plurality of geometries, which may be determined based on the required functionality of the pressure to be applied, and may be calculated by, e.g. finite element method (FEM) analyses.

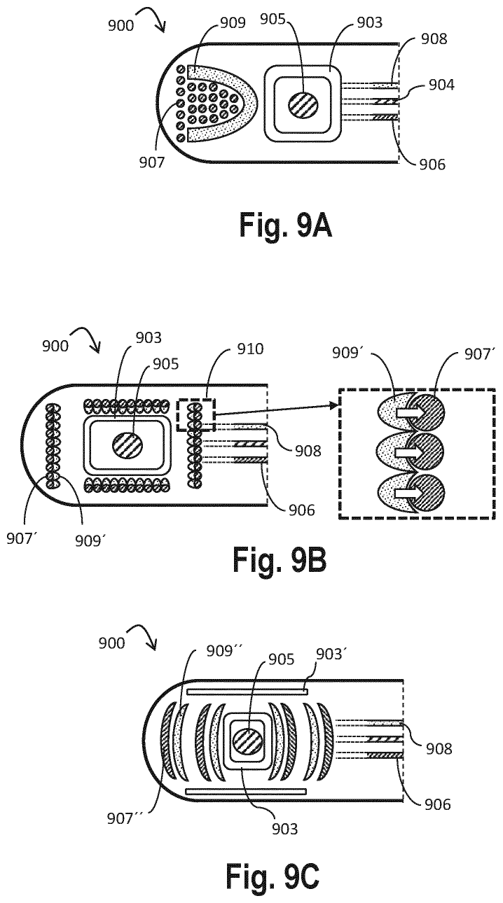

Further exemplary embodiments, all comprising the preferred functionality as in the embodiment of FIG. 7 are shown in FIGS. 9A-9C. In FIG. 9A part of a gripper 900 is shown in the form of a finger, where the engaging surface 903 is located towards the rear of the finger, surrounding the first outlet 905, to which the vacuum line of first channel 904 is connected. The second channel 906, which serves as a negative pressure line as per the preferred embodiment, is connected to a plurality of outlets 907 located at the front of the gripper. The third channel 908, which serves as a positive (high) pressure line, is connected to a horseshoe-shaped outlet 909. The horseshoe-shaped outlet 909 is configured in use to direct positive pressure towards the array of negative (low) pressure outlets 907, such that a trap for liquid in the vicinity of the gripper is provided. That is to say, liquid is directed from the horseshoe-shaped outlet 909 towards the plurality of outlets 907, which are configured to suck the liquid away.

In FIG. 9B, the engaging surface 903 is located at the centre of the gripper finger. To each side of the engaging surfaces as shown an array of outlets 907′, each connected to the second channel 906 configured to act as a negative pressure line, is provided. To better illustrate the outlets, a close-up view of the outlets in demarcated area 910 is provided. The outlets 907′ connected to the second channel are shown as substantially circular in shape. Adjacent each outlet connected to the second channel 906 is an outlet 909′ connected to the third channel 908. The third channel 908 is configured to act as a positive pressure line, and the corresponding outlets 909′ are shown as somewhat crescent-shaped. The crescent shape of each outlet 909′ has a similar effect as the horseshoe shaped outlet 909 shown in FIG. 9A, such that liquid is directed towards each corresponding negative pressure outlet to be sucked away from the grippe. The arrows in the close-up view illustrate the direction of air from the crescent-shaped outlets 909′ of the positive pressure line towards the circular outlets 907′ of the negative pressure line. An advantage of including outlets with the described functionality on each side of the operable gripper body is that liquid occurring on the gripper due to contamination, which may be present on the sides and rear of the gripper and not just at the leading edge at the front, may be removed.

In FIG. 9C, a gripper finger is shown with the engaging surface 903 comprising a continuous ring surrounding the first outlet 905, and additional lines 903′ located at each lateral side of the finger. Outlets 907″, 909″ connected to the second and third channels 906, 908 are located both to the front and rear of the gripper finger at either side of the central engaging surface. At the front and rear there are located two outlets 909″ configured to provide a positive pressure directed towards respective negative pressure outlets 907″. Advantageously, and similarly to the embodiment of FIG. 9B, the arrangement of outlets as per the embodiment of FIG. 9C results in the removal of liquid present on the gripper due to e.g. contamination, i.e. liquid that may be present on the sides and rear of the gripper in addition to the leading edge at the front. A further advantage of the embodiment of Figure C is that the additional lines of the engaging surface at the lateral sides of the gripper body result in greater stability when engaging an object such as a substrate. It is noted that it may be preferable to keep the engaging surface to as small an area as possible so as to minimise contact regions.

It is also possible that the second and third channels are each connected to a high or positive pressure from either a single or joint positive (high) pressure source. Similarly, it is also possible that the second and third channels are each connected to a negative (low) pressure source from either a single or joint negative pressure source, which may optionally be a wet vacuum source.

The material properties of the gripper may be configured to attract or repel fluid to further optimise the suction or repulsion of fluid when combined with a positive pressure line or a negative pressure line, or a combination thereof. Optionally therefore, the gripper body comprises a porous material so as to absorb fluid in the vicinity of the gripper. The porous material may also be connected to an operable negative or low pressure line so as to remove the fluid absorbed by the gripper.

Optionally, the gripper comprises a hydrophilic coating so as to attract fluid.

Optionally, the gripper comprises a hydrophobic coating so as to repel fluid.

The invention further relates to a method of holding an object, such as a substrate, comprising locating a gripper according an embodiment of the invention adjacent to a planar surface of an object. The gripper may be located above or below the object, depending on whether the vacuum clamps the lower or upper surface of the gripper body, respectively. A negative pressure may be applied to the second channel so as to create a vacuum or suction force at the at least one outlet, to remove fluid in the vicinity of the at least one outlet and thereby away from the engaging surface of the gripper. Alternatively, a positive pressure may be applied to the second channel so as to create a repulsive force at the at least one outlet, to repel fluid in the vicinity of the at least one outlet and thereby away from the engaging surface of the gripper. When the fluid in the vicinity of the gripper is removed, either by means of suction or repulsion, the negative or positive pressure applied to the second channel is removed. A vacuum is then applied to the first channel to operate a vacuum clamp to secure the object to the gripper.

The method may additionally comprise applying a positive or negative pressure to the third channel at or near to the same time as a pressure is applied to the second channel, and removing the positive or negative pressure applied to the third channel at or near to the same time as the pressure applied to the second channel is removed.

The embodiments disclosed herein remove or direct water away from the substrate at least in the region the gripper. The size and shape of the gripper, its corresponding at least one outlet of the second channel, and optionally the at least one outlet of the third channel, may be selected to optimize liquid reduction across an object such as a substrate. Thus the application of positive pressure and/or negative pressure can minimize the thermal load resulting from liquid droplets on the substrate and the temperature of the substrate can be controlled, avoiding thermal defects.

The invention further relates to a lithographic apparatus, which may comprise one or more of the components of the lithographic apparatus LA shown in FIG. 1, such as the projection system. The lithographic apparatus may further comprise an object holder comprising the gripper of the invention.

Although specific reference may be made in this text to the use of a lithographic apparatus in the manufacture of ICs, it should be understood that the lithographic apparatus described herein may have other applications. Possible other applications include the manufacture of integrated optical systems, guidance and detection patterns for magnetic domain memories, flat-panel displays, liquid-crystal displays (LCDs), thin-film magnetic heads, etc.

Although specific reference may be made in this text to embodiments of the invention in the context of a lithographic apparatus, embodiments of the invention may be used in other apparatus. Embodiments of the invention may form part of a mask inspection apparatus, a metrology apparatus, or any apparatus that measures or processes an object such as a wafer (or other substrate) or mask (or other patterning device). These apparatus may be generally referred to as lithographic tools. Such a lithographic tool may use vacuum conditions or ambient (non-vacuum) conditions.

Although specific reference may have been made above to the use of embodiments of the invention in the context of optical lithography, it will be appreciated that the invention, where the context allows, is not limited to optical lithography and may be used in other applications, for example imprint lithography.

Where the context allows, embodiments of the invention may be implemented in hardware, firmware, software, or any combination thereof. Embodiments of the invention may also be implemented as instructions stored on a machine-readable medium, which may be read and executed by one or more processors. A machine-readable medium may include any mechanism for storing or transmitting information in a form readable by a machine (e.g., a computing device). For example, a machine-readable medium may include read only memory (ROM); random access memory (RAM); magnetic storage media; optical storage media; flash memory devices; electrical, optical, acoustical or other forms of propagated signals (e.g. carrier waves, infrared signals, digital signals, etc.), and others. Further, firmware, software, routines, instructions may be described herein as performing certain actions. However, it should be appreciated that such descriptions are merely for convenience and that such actions in fact result from computing devices, processors, controllers, or other devices executing the firmware, software, routines, instructions, etc. and in doing that may cause actuators or other devices to interact with the physical world.

While specific embodiments of the invention have been described above, it will be appreciated that the invention may be practiced otherwise than as described. The descriptions above are intended to be illustrative, not limiting. Thus it will be apparent to one skilled in the art that modifications may be made to the invention as described without departing from the scope of the claims set out below. Other aspects of the invention are set out as in the following numbered clauses:

1. A gripper for an object handler comprising an engaging surface for engaging a surface of an object, and a first channel connected to a first outlet, said first outlet being configured to operate, during use, as a vacuum clamp arranged to secure the engaging surface to the surface of the object, characterized in that the gripper further comprises a second channel arranged to be connected to a pressure source, and at least one second outlet arranged adjacent to the engaging surface and connected to the second channel.

2. The gripper of clause 1, wherein the second channel is configured to alternate between operation as a negative pressure line, and operation as a positive pressure line.

3. The gripper of clause 1 or 2, wherein the second channel is a negative pressure line configured to apply suction for removal of fluid.

4. The gripper of clause 3 wherein the second channel is connected to a wet vacuum supply.

5. The gripper of any of clauses 2-4 wherein the pressure in the second channel is in the range of 0 to −55 kPa.

6. The gripper of clause 1 or 2, wherein the second channel is a positive pressure line configured to apply a repulsive force to repel fluid.

7. The gripper of clause 6 wherein the pressure in the second channel is in the range of 0 to 200 kPa.

8. The gripper of any preceding clause wherein the at least one second outlet is located between an outer edge of the gripper and the engaging surface of the gripper.

9. The gripper of any preceding clause wherein the at least one second outlet is arranged between the first outlet and the engaging surface of the gripper.

10. The gripper of any preceding clause wherein the at least one second outlet is arranged on the leading edge of the gripper.

11. The gripper according to any preceding clause, wherein the at least one second outlet is substantially circular.

12. The gripper according to any preceding clause, wherein the at least one second outlet is substantially linear.

13. The gripper of any preceding clause, wherein the at least one second outlet is a plurality of second outlets.

14. The gripper of any preceding clause, wherein the gripper further comprises a groove adjacent to and in communication with the at least one second outlet.

15. The gripper of any preceding clause, further comprising a third channel having at least one third outlet connected thereto, said third outlet located adjacent to the at least one second outlet of the second channel.

16. The gripper of clause 15 wherein the third channel is configured to alternate between operation as a negative pressure line, and operation as a positive pressure line.

17. The gripper of clause 15 wherein the third channel is a positive pressure line configured to apply a repulsive force.

18. The gripper of clause 17, wherein the pressure in the third channel is in the range of 0 to 200 kPa.

19. The gripper of clause 9 wherein the third channel is a negative pressure line configured to apply suction for removal of fluid.

20. The gripper of clause 19 wherein the pressure in the third channel is in the range of 0 to −55 kPa.

21. The gripper according to any of clauses 15-20, wherein the at least one third outlet is substantially circular.

22. The gripper according to any of clauses 15-20, wherein the at least one third outlet is substantially linear.

23. The gripper of any of clauses 15-22 wherein the at least one third outlet is a plurality of third outlets.

24. The gripper of clauses 15-23, wherein the gripper further comprises a groove adjacent to and in communication with the at least one third outlet.

25. The gripper of any of clauses 15-24 wherein the at least one third outlet of the third channel is arranged to cooperate with the at least one second outlet of the second channel.

26. The gripper of any preceding clause wherein the application of pressure to the second and/or third channels is configured to control a temperature of the object.

27. The gripper according to any preceding clause, wherein the engaging surface further comprises a porous material.

28. The gripper according to any preceding clause, wherein the engaging surface further comprises a hydrophilic or hydrophobic coating.

29. The gripper according to any preceding clause, wherein the engaging surface of the gripper is shaped by one or more lines.

30. The gripper according to clause 29 wherein the one or more lines are straight.

31. The gripper according to clause 29 wherein the one or more lines are curved.

32. The gripper according to any of clauses 29-31 wherein the one or more lines form a continuous surface.

33. A lithographic apparatus comprising the gripper of any preceding clause.

34. A method of holding an object comprising:
locating a gripper according to any preceding clause underneath an object,
applying a first pressure through the second channel,
removing the first pressure through the second channel, and
applying a vacuum to operate a vacuum clamp to secure the object to the gripper.

35. The method of clause 34 wherein the gripper comprises a third channel according to any of clauses 15-25, and further comprising applying a second pressure through the third channel.

36. The method of clause 35 wherein the first pressure and the second pressure are configured to cooperatively remove liquid.

37. The method of any of clauses 34-36 wherein the first pressure is a negative pressure to remove fluid from the vicinity of the at least one outlet.

38. The method of any of clauses 34-36 wherein the first pressure is a positive pressure to repel fluid from the vicinity of the at least one outlet.

39. The method of any of clauses 34-38 wherein the second pressure is a negative pressure to remove fluid from the vicinity of the at least one outlet of the third channel.

40. The method of any of clauses 34-38 wherein the second pressure is a positive pressure to repel fluid from the vicinity of the at least one outlet of the third channel.

41. The method of any of clauses 34-40 wherein the pressure is configured to control a temperature of the object.

42. A computer program comprising computer readable instructions configured to cause a computer to carry out the method according to any of clauses 34-41.

43. A computer readable medium carrying a computer program according to clause 42.

44. A computer apparatus comprising: a memory storing processor readable instructions; and a processor arranged to read and execute instructions stored in said memory; wherein said processor readable instructions comprise instructions arranged to control the computer to carry out a method according to any of clauses 34-41.

1. A gripper for an object handler, the gripper comprising:
an engaging surface for engaging a surface of an object,
a first channel connected to a first outlet, the first outlet being configured to operate, during use, as a vacuum clamp arranged to secure the engaging surface to the surface of the object,
a second channel arranged to be connected to a pressure source, and
at least one second outlet arranged adjacent to the engaging surface and connected to the second channel.

2. The gripper of claim 1, wherein the second channel is configured to alternate between operation as a negative pressure line, and operation as a positive pressure line.

3. The gripper of claim 1, wherein the second channel is a negative pressure line configured to apply suction for removal of fluid.

4. The gripper of claim 3, wherein the second channel is connected to a wet vacuum supply.

5. (canceled)

6. The gripper of claim 1, wherein the second channel is a positive pressure line configured to apply a repulsive force to repel fluid.

7. (canceled)

8. The gripper of claim 1, wherein the at least one second outlet is located between an outer edge of the gripper and the engaging surface of the gripper.

9. The gripper of claim 1, wherein the at least one second outlet is arranged between the first outlet and the engaging surface of the gripper.

10. The gripper of claim 1, wherein the at least one second outlet is arranged on a leading edge of the gripper.

11.-13. (canceled)

14. The gripper of claim 1, further comprising a groove adjacent to and in communication with the at least one second outlet.

15. The gripper of claim 1, further comprising a third channel having at least one third outlet connected thereto, the third outlet located adjacent to the at least one second outlet of the second channel.

16. The gripper of claim 15, wherein the third channel is configured to alternate between operation as a negative pressure line, and operation as a positive pressure line.

17. The gripper of claim 15, wherein the third channel is a positive pressure line configured to apply a repulsive force.

18. (canceled)

19. The gripper of claim 15, wherein the third channel is a negative pressure line configured to apply suction for removal of fluid.

20.-23. (canceled)

24. The gripper of claim 15, further comprising a groove adjacent to and in communication with the at least one third outlet.

25.-32. (canceled)

33. A lithographic apparatus comprising the gripper of claim 1.

34. A method of holding an object, the method comprising:
locating a gripper according to claim 1 underneath an object,
applying a first pressure through the second channel,
removing the first pressure through the second channel, and
applying a vacuum to operate a vacuum clamp to secure the object to the gripper.

35. The method of claim 34, wherein the gripper comprises a third channel, and further comprising applying a second pressure through the third channel.

36. The method of claim 35, wherein the first pressure and the second pressure are configured to cooperatively remove liquid.

37.-40. (canceled)

41. The method of claim 34, wherein the pressure is configured to control a temperature of the object.

42. A non-transitory computer-readable medium having computer readable instructions therein, the instructions, when executed by a computer system, configured to cause the computer system to carry out at least the method according to claim 34.

43.-44. (canceled)
